(19) United States
(12) Patent Application Publication
(10) Pub. No.: US 2003/0216003 A1
(43) Pub. Date: Nov. 20, 2003

(54) Method of forming flash memory device

(76) Inventors: Sang Ick Lee, Kyoungki-do (KR); Hyung Hwan Kim, Kyoungki-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/331,063

(22) Filed: Dec. 30, 2002

(30) Foreign Application Priority Data
May 17, 2002 (KR) 2002-27541

(51) Int. Cl. H01L 29/788; H01L 21/336

(52) U.S. Cl. 438/264; 257/315

(57) ABSTRACT

Method of forming flash memory device is disclosed, more particularly, method of forming self-aligned floating gate by performing Chemical Mechanical Polishing (abbreviated as “CMP”) process using slurry having higher polishing selectivity to oxide films than to nitride films and slurry having higher polishing selectivity to polysilicon than to oxide films.

### BACKGROUND

1. Technical Field

A method of forming flash memory device is disclosed, more particularly, a method of forming self-aligned floating gate is disclosed by performing Chemical Mechanical Polishing (abbreviated as “CMP”) process using slurry having higher polishing selectivity to oxide films than to nitride films and slurry having higher polishing selectivity to polysilicon than to oxide films.

2. Description of the Related Art

Flash memory is a memory wherein a programming and an erasing operation are simultaneously performed while electrons are passing through a tunnel oxide film formed between a self-aligned floating gate and a semiconductor substrate. Flash memory is also a nonvolatile memory wherein stored information is not damaged even when power is turned off and the information can be freely inputted/outputted by an electrical method.

FIGS. 1a through 1g show a method of fabricating a conventional self-aligned floating gate. The thickness indicated for the various layers are approximations.

Referring to FIG. 1a, a pad oxide film 3 is formed with a thickness of 100 Å on a silicon substrate 1, and a pad nitride film 5 is sequentially formed at a thickness of 2500 Å above the pad oxide film 3.

Referring to FIG. 1b, While a selective CMP process using mask(not shown) is performed on the resultant structure, the pad nitride film 5 at a thickness of 2500 Å, the pad oxide film 3 at a thickness of 100 Å and the silicon substrate 1 at a thickness of 3000 Å are sequentially removed.

As a result, the pad nitride film pattern 5-1, the pad oxide film pattern 3-1 and a trench 7 are formed.

Referring to FIG. 1c, a isolation oxide film 9 is formed at a thickness of 6000 Å on the entire surface including the trench 7.

Referring to FIG. 1d, a CMP process using the conventional CMP slurry for oxide film is performed on the isolation oxide film 9 using the pad nitride film pattern 5-1 as an etching barrier film, to isolate an active region 13.

Referring to FIG. 1e, the pad nitride film pattern 5-1 and the pad oxide film pattern 3-1 are selectively wet-etched until the substrate 1 is exposed, and then a tunnel oxide film 15 is formed on the exposed substrate 1.

Referring to FIG. 1f, a polysilicon layer 17a is formed on with a thickness of 1700 Å on the isolation oxide film 9.

Referring to FIG. 1g, the polysilicon 17a is polished using slurry for polysilicon until the surface of the isolation oxide film 9 is exposed to form the lower electrodes of floating gate 17.

As shown in FIG. 1d, the slurry used in performing a CMP process on the isolation oxide film 9 is common CMP slurry for oxide films with a pH ranging from 7 to 8 including abrasives such as colloidal or fumed SiO₂. The slurry has a polishing selectivity of nitride film:oxide film ranging from 1:2 to 1:4.

However, in the CMP process using the conventional CMP slurry, the isolation oxide film 9 is etched, a erosion effect is generated on the pad nitride film 5 and a dishing effect is generated on the oxide film 9 because the pad nitride film 5 and the isolation oxide film 9 have a small difference in an etching selectivity, thereby the thickness of the isolation oxide film 9 is differentiated.

In addition, the polysilicon 17a layer has an irregular thickness, because of the irregular thickness of the isolation oxide film 9. As a result, the reliability of the device is degraded.

There is also a problem in that the pad nitride film 5 should be more thickly stacked than required in order to obtain a predetermined thickness of the isolation oxide film.

In addition, because the slurry for polysilicon is general slurry for oxide films comprising abrasives such as CeO₂ or SiO₂, the isolation oxide film 9 serving as an etching barrier film is polished with the polysilicon 17a.

As a result, it is difficult to measure an approximate end point and because isolation oxide film 9 is formed thicker than necessary, the process cost is unnecessarily increased.

### SUMMARY OF THE DISCLOSURE

More reliable semiconductor devices are formed with films having uniform thicknesses using a CMP slurry having excellent polishing selectivity to oxide films and polysilicon.

A disclosed method for forming a flash memory device comprises:

(a) forming a pad oxide film and a pad nitride film on the substrate;

(b) selectively pattering the pad nitride film, the pad oxide film and the substrate there under to form a trench;

(c) forming a isolation oxide film on the resultant structure;

(d) performing a CMP process on the isolation oxide film using a first slurry of a pH ranging from 2 to 7 until the pad nitride film is exposed to form isolation oxide film pattern for separating an active region, wherein the first slurry comprises a solvent, an abrasive and a first additive and the first additive is a homo-polymer of hydrocarbon compound including carboxylic acid(—COOH), nitro(—NO₂) or amide(—NH—CO—) as a functional group; a copolymer of hydrocarbon compound including carboxylic acid(—COOH), nitro(—NO₂) or amide(—NH—CO—) as a functional group; or mixtures thereof;

(e) removing the pad nitride film pattern and the pad oxide film pattern in the active region to expose a semiconductor substrate of the active region;

(f) forming a tunnel oxide film on the substrate in the active region by performing an oxidation process;

(g) forming a polysilicon layer on the resultant structure; and

(h) performing a CMP process on the polysilicon layer using a second slurry having a pH ranging from 8 to 11 until the isolation oxide film is exposed to form a floating gate, wherein the second slurry comprises a solvent, an abrasive and a second additive and the second additive is ammonium hydroxide or an amine compound having a functional group among —N(OH), —NH(OH) and —NH₂(OH).

The CMP slurry for oxide film of step (d) comprises hydrochloric acid as pH adjusting agent, and it is added to the slurry composition so it has a pH ranging from 2 to 7, more preferably, from 4 to 7, because the slurry composition has high selectivity to oxide films under the acidic condition.

Accordingly, the added amount of hydrochloric acid is not specifically predetermined, but the proper amount of hydrochloric acid is determined to maintain the above pH range of the CMP slurry composition.

The solvent of the step (d) is distilled water or ultra pure water and the abrasive of the step (d) is Ceria (CeO₂), colloidal or fumed SiO₂.

The polymer as the additive has molecular mass ranging from 1000 to 10000.

The preceding functional group of carboxylic acid(—COOH), nitro(—NO₂) or amide(—NH—CO—) included in hydrocarbon compound may be changed into —OH, —C═O, —COO⁻, —NH₂, —NO, —NO₂ or —NHCO in the process of synthesis of polymer. Preferred the compounds including such a structure are selected from the group consisting of carboxymethylcellulose sodium salt, methyl vinyl ether, poly(acrylic acid), poly(ethylene glycol), polygalacturonic acid and combinations thereof, preferably alpha-cellulose, thereby resulting in improving selectivity of oxide films.

The CMP slurry composition for oxide film of the step (d) has a ratio of parts by weight of solvent:CeO₂ as abrasive ranging from 100:0.5 to 100:2, and that of solvent:additive ranging from 100:0.1 to 100:1.5.

On the contrary, the CMP slurry composition for oxide film of the step (d) has a ratio of parts by weight of solvent:SiO₂ as abrasive ranging from 100:10 to 100:33, more preferably, 100:14 to 100:33, and of solvent:additive ranging from 100:0.1 to 100:1.5, more preferably, 100:0.1 to 100:1.

The CMP slurry composition for oxide film for oxide film of the step (d) has a polishing selectivity of nitride film:oxide film ranging from 1:20 to 1:200, more preferably, from 1:50 to 1:200.

In addition, the CMP slurry for polysilicon of the step (h) comprises phosphoric acid as pH adjusting agent, and is added to maintain a pH ranging from 8 to 11, more preferably, from 10 to 11, thereby improving selectivity to polysilicon.

Accordingly, the amount of adding phosphoric acid is not specifically predetermined, but the proper amount is determined to maintain the above pH range of the slurry composition.

The solvent of the step (h) is distilled water or ultra pure water and the abrasive of the step (h) is SiO₂.

The second additive of the step (h) is selected from the group consisting of tetraethyl ammonium hydroxide, tetrabutyl ammonium hydroxide, dimethylamine, methylamine, tetramethyl ammonium hydroxide and combinations thereof.

The CMP slurry composition for polysilicon of the step (h) has a parts by weight of solvent:abrasive ratio ranging from 100:0.6 to 100:12, more preferably, from 100:0.6 to 100:10, and that of solvent:additive ranging from 100:0.5 to 100:5.

The CMP slurry composition for polysilicon of the step (h) has a polishing selectivity of oxide film:polysilicon ranging from 1:50 to 1:30, more preferably, from 1:100 to 1:300.

The CMP process for oxide film of the step (d) comprises two steps.

(a) the first step of performing a CMP process using an oxide film slurry of a pH ranging from 7 to 8 including an abrasive of SiO₂, which is finished up remaining the isolation film on the pad nitride film by a predetermined thickness; and

(b) the second step of performing a CMP process using the first slurry to exposed the pad nitride film.

Here, the thickness of the remaining isolation oxide film after CMP in the first step is from 1 to 50%, more preferably, from 16 to 20%, of that before CMP in the first step.

The slurry for oxide film has a polishing selectivity of nitride film:oxide film ranging from 1:2 to 1:4.

For instance, a portion of the device isolation film 29 is removed using the first conventional slurry for oxide films to have from 1 to 50%, of its initial thickness.

### BRIEF DESCRIPTION OF THE DRAWINGS

FIGS. 1a through 1g are diagrams illustrating method of forming flash memory device according to conventional art.

FIGS. 2a through 2g are diagrams illustrating method of forming flash memory device according to the disclosed methods.

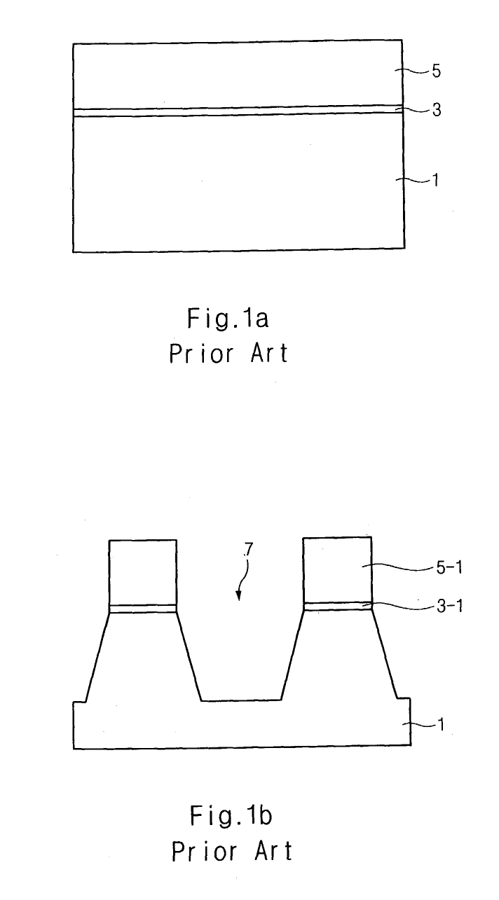

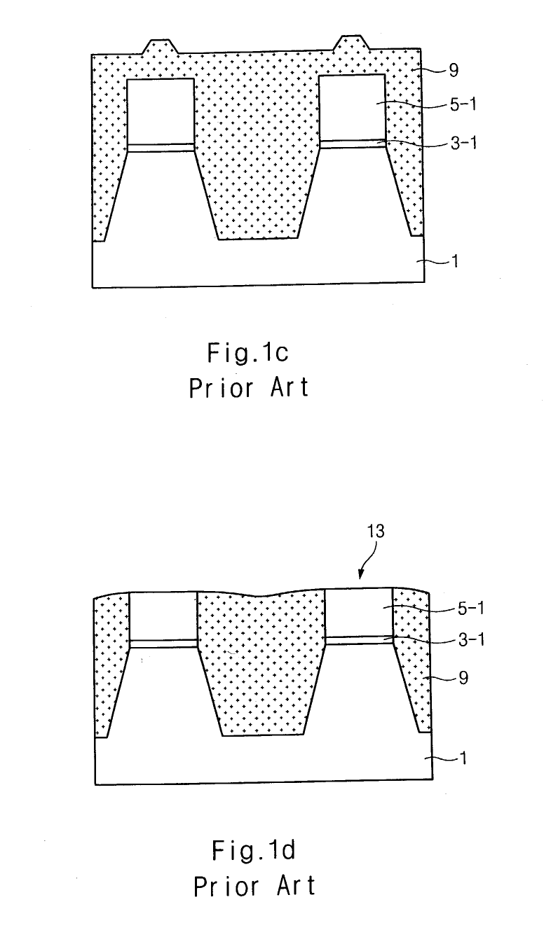

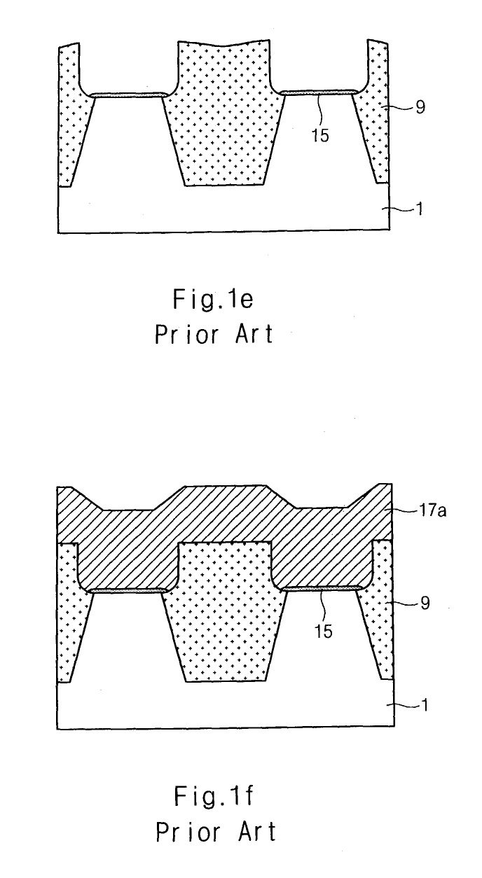

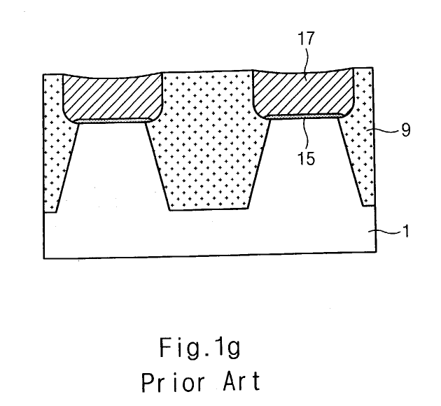

### DETAILED DESCRIPTION OF THE PRESENTLY PREFERRED EMBODIMENTS

Methods of fabricating semiconductor device will now be described in more detail in reference to the accompanying drawings. All layer thicknesses, component ratios and selectivities indicated are approximations and actual thicknesses, component ratios and selectivities may vary without departing from the scope of this disclosure.

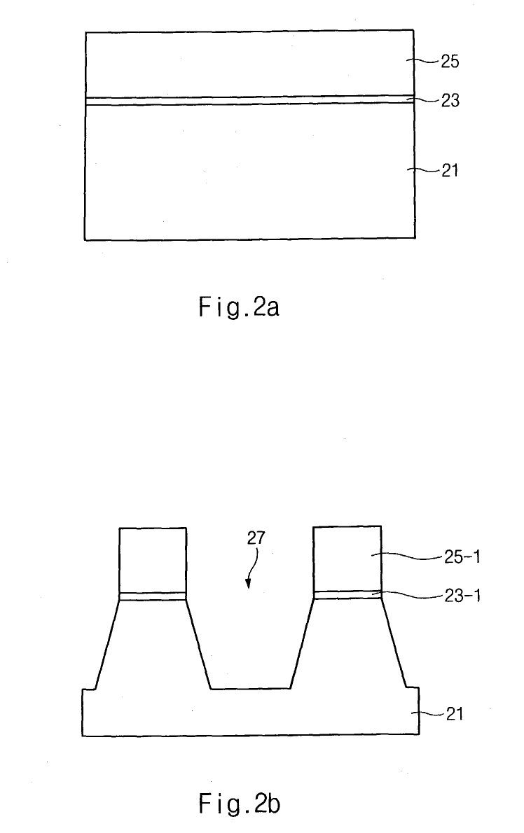

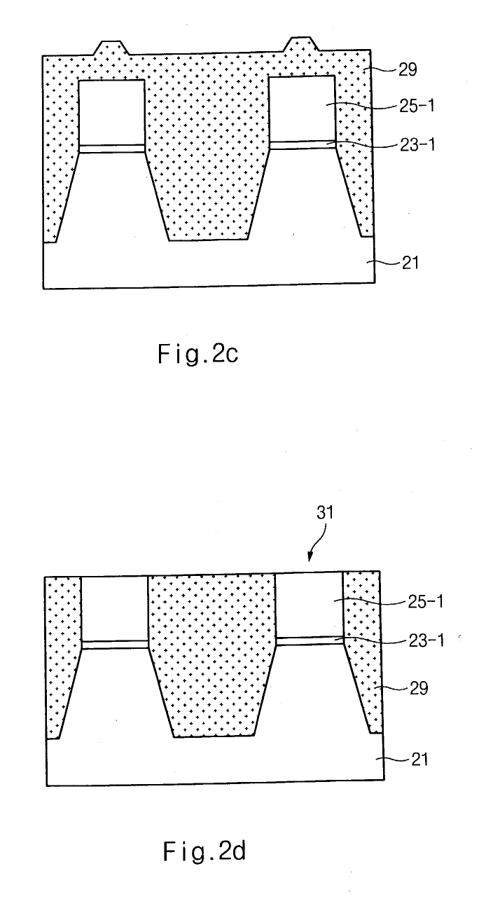

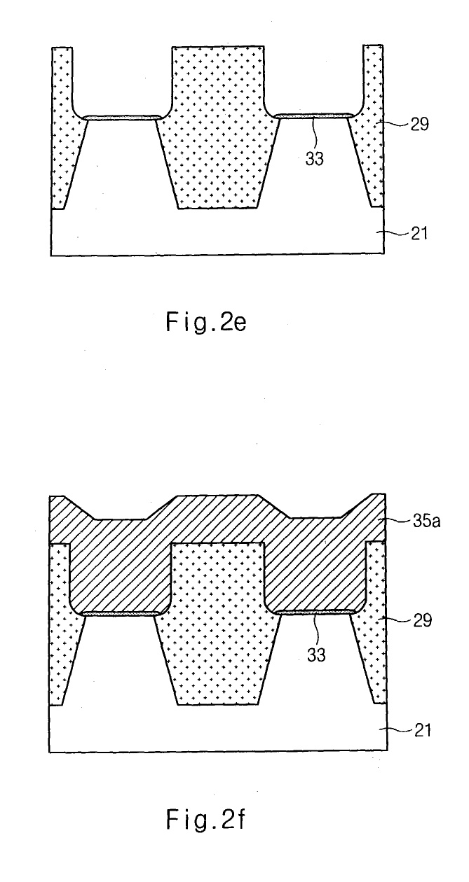

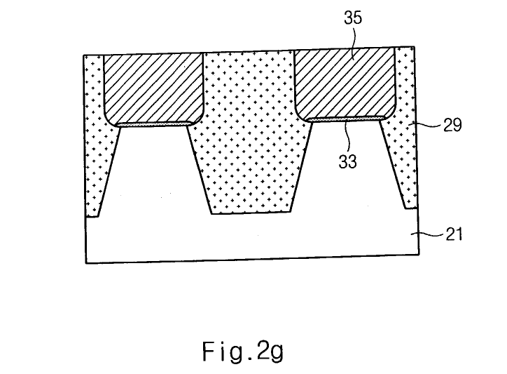

FIGS. 2a through 2g are diagrams illustrating method of forming flash memory device accordance with a preferred embodiment.

Referring to FIG. 2a, a pad oxide film 23 is formed at a thickness ranging from 50 to 100 Å on the silicon substrate 21, and then a pad nitride film 25 is formed at a thickness ranging from 1500 to 2000 Å on the pad oxide film 23.

Referring to FIG. 2b, while a selective polishing process using mask(not shown)is performed on the resultant structure, the pad nitride film 25 at a thickness of 2500 Å, the pad oxide film 23 at a thickness of 100 Å and the silicon substrate 21 at a thickness of 3000 Å are sequentially removed.

As a result, a pad nitride film pattern 25-1, a pad oxide film pattern 23-1 and a trench 27 are formed.

Referring to FIG. 2c, the isolation oxide film 29 is formed at a thickness ranging from 5000 to 6000 Å on the entire surface of the above structure.

Referring to FIG. 2d, a CMP process using the slurry for oxide film is performed on the remaining isolation oxide film 29 to separate a device active region 31 until the pad nitride pattern 25-1 is exposed.

Here, the pad nitride film pattern 25-1 is scarcely polished because the disclosed slurry has high etching selectivity to oxide films. As a result, the pad nitride film pattern 25-1 remains at its initial thickness ranging from 1500 to 2000 Å.

The CMP process comprises two steps. In the first step, the device isolation film is removed to have a portion on the pad nitride film by performing a CMP process using the conventional slurry for oxide films. Secondly, a target is completely removed by performing a CMP process using the slurry for oxide film of the present invention, the target that is the isolation oxide film above the pad nitride film.

For instance, a portion of the device isolation film 29 is removed using the first conventional slurry for oxide films to have from 1 to 50%, and preferably from 16 to 20% of its initial thickness.

Thereafter, a CMP process is performed on the remaining isolation oxide film 29 until the surface of pad nitride film pattern 25-1 is exposed.

As a result, the isolation oxide film 29 on the pad nitride film pattern 25-1 is completely removed.

Referring to FIG. 2e, the pad nitride film pattern 25-1 and the pad oxide film pattern 23-1 are selectively wet-etched until the substrate 21 is exposed, and then a tunnel oxide film 33 is formed on the exposed substrate 21.

Referring to FIG. 2f, polysilicon 35a is formed at a thickness ranging from 1300 to 1700 Å above the tunnel oxide film 33.

Referring to FIG. 2g, using slurry for polysilicon, the polysilicon 35a is polished until the isolation oxide film 29 is exposed to form the lower electrodes of floating gate 35.

Accordingly, the damage of isolation oxide film 29 during the CMP process using slurry for polysilicon of the present invention can be prevented. As a result, the process cost and thickness difference of film can be reduced, thereby improving reliability of device.

Method of Fabricating Slurry of Present Invention

### EXAMPLE 1

Slurry for Oxide Films including CeO₂

According to the amount described in the following Table 1, CeO₂ as an abrasive is added in ultra pure water, stirred not to be condensed, and then alpha-cellulose (CAS#9004-34-6) as an additive is further added.

While the composition is stirred, hydrochloric acid as a pH adjusting agent is added in the composition to have a pH of 5. The composition is further being stirred for about 30 minutes until it is completely mixed and stabilized. As a result, slurry of the present invention having high selectivity to oxide films is fabricated.

TABLE 1

| | CeO₂ | Ultra Pure Water | Alpha-cellulose |
|---|---|---|---|
| A | 10 g | 1000 g | 5 g |
| B | 15 g | 1000 g | 5 g |
| C | 10 g | 1000 g | 10 g |

### EXAMPLE 2

Slurry for Oxide Films including SiO₂

According to the amount described in the following Table 2, SiO₂ as an abrasive is added in ultra pure water, stirred not to be condensed, and then alpha-cellulose as an additive is further added.

While the composition is stirred, hydrochloric acid as a pH adjusting agent is added in the composition to have a pH of 5. The composition is further being stirred for about 30 minutes until it is completely mixed and stabilized. As a result, slurry of the present invention having high selectivity to oxide films is fabricated.

TABLE 2

| | SiO₂ | Ultra Pure Water | Alpha-cellulose |
|---|---|---|---|
| D | 10 g | 1000 g | 5 g |
| E | 15 g | 1000 g | 5 g |
| F | 10 g | 1000 g | 10 g |

### EXAMPLE 3

Preparation of Slurry for Polysilicon

According to the quantities of Table 3, SiO₂ as abrasive is added in ultra pure water, stirred not to be condensed, and then tetramethyl ammonium hydroxide(CAS#75-59-2) as additive is further added in the ultra pure water.

While the compound is stirred, phosphoric acid as a pH adjusting agent is added in the compound to maintain a pH of 10. The compound is further being stirred for about 30 minutes until it becomes completely mixed and stabilized. As a result, slurry of the present invention having high selectivity to oxide films is fabricated.

TABLE 3

| | | | Ammonium Hydroxide |
|---|---|---|---|
| | SiO₂ | Ultra Pure Water | or Amine |
| G | 112 g | 1000 g | 6 g |
| H | 53 g | 1000 g | 5 g |
| I | 10 g | 1000 g | 5 g |

Polishing Selectivity of Slurry

### EXAMPLE 4

Polishing Selectivity of Slurry for Oxide Films including CeO₂

Using the slurry composition of the Example 1, a CMP process is performed on silicon oxide films ‘Ox’ and silicon nitride films ‘SiN’, respectively, at a head pressure and a polishing pressure of 5 psi, and at a table rotation frequency of 30 rpm. Table 4 shows the polishing amount and selectivity as a result of the CMP process.

TABLE 4

| | Polishing Amount of | polishing Selectivity |
|---|---|---|
| | oxide film (Ox, Å/min) | (Ox/SiN) |
| A | 3,000 | 80 |
| B | 4,000 | 50 |
| C | 2,500 | 60 |

### EXAMPLE 5

Polishing Selectivity of Slurry for Oxide Films including SiO₂

Using the slurry composition of Example 2, a CMP process is performed on silicon oxide films ‘Ox’ and silicon nitride films ‘SiN’, respectively, at a head pressure and a polishing pressure of 5 psi, and at a table rotation frequency of 30 rpm. Table 5 shows the polishing amount and selectivity as a result of the CMP process.

TABLE 5

| | Polishing Amount of | Polishing Selectivity |
|---|---|---|
| | oxide film (Ox, Å/min) | (Ox/SiN) |
| D | 3,000 | 80 |
| E | 3,000 | 50 |
| F | 2,500 | 60 |

### EXAMPLE 6

Polishing Selectivity of Slurry for Polysilicon

Using the slurry composition of the example 3, a CMP process is performed on polysilicon films ‘poly-Si’ and silicon oxide films ‘Ox’, respectively, at a head pressure and a polishing pressure of 5 psi, and at a table rotation frequency of 30 rpm. Table 6 shows the polishing amount and selectivity as a result of the CMP process.

TABLE 6

| | Polishing Amount of | Polishing Selectivity |
|---|---|---|
| | Polysilicon (Poly-Si, Å/min) | (Poly-Si/Ox) |
| G | 10,000 | 50 |
| H | 6,000 | 100 |
| I | 4,500 | 300 |

As discussed earlier, if a CMP process is performed on a isolation film using slurry having a selectivity of nitride film:oxide film ranging from 1:>50, it is possible to prevent a pad nitride film from being eroded and a pad oxide film from being dished. A isolation oxide film can be planarized because its thickness difference according to pattern concentration is reduced. The damage of films during the process is decreased and the thickness of stacked films is reduced. As a result, the costs can also be reduced.

Additionally, if a CMP process is performed on polysilicon using slurry having a polishing selectivity of oxide film:polysilicon ranging from 1:50 to 1:300, it is possible to prevent a isolation film from being polished and to measure a precise end point. As a result, a reliable flash memory device can be fabricated because thickness difference of films is reduced and polysilicon having uniform thickness is formed on the whole surface of wafer.

What is claimed is:

1. A method for forming a flash memory device comprising:
(a) forming a pad oxide film and a pad nitride film on a substrate;
(b) selectively pattering the pad nitride film, the pad oxide film and the substrate to form a trench;
(c) forming a isolation oxide film on the resultant structure;
(d) performing a CMP process on the isolation oxide film using a first slurry of pH ranging from 2 to 7 until the pad nitride film is exposed to form an isolation oxide film pattern for separating an active region, wherein the first slurry comprises a solvent, an abrasive and a first additive and the first additive is selected from the group consisting of a homo-polymer of hydrocarbon compound including carboxylic acid(—COOH) group, a homo-polymer of hydrocarbon compound including nitro(—NO₂) group, a homo-polymer of hydrocarbon compound including amide(—NH—CO—) group, a copolymer of hydrocarbon compound including carboxylic acid(—COOH) group, a copolymer of hydrocarbon compound including nitro(—NO₂) group, a copolymer of hydrocarbon compound including amide(—NH—CO—) group and mixtures thereof;
(e) removing the pad nitride film pattern and the pad oxide film pattern in the active region to expose the substrate in the active region;
(f) forming a tunnel oxide film on the substrate in the active region by performing an oxidation process;
(g) forming a polysilicon layer on the resultant structure; and
(h) performing a CMP process on the polysilicon layer using a second slurry of pH ranging from 8 to 11 until the isolation oxide film is exposed to form a floating gate, wherein the second slurry comprises a solvent, an abrasive and a second additive and the second additive comprises ammonium hydroxide or an amine compound.

2. The method according to claim 1, wherein the amine compound comprises a functional group selected from the group consisting of —N(OH), —NH(OH) and —NH₂(OH).

3. The method according to claim 1, wherein the first slurry composition of the (d) step has a pH ranging from 4 to 7.

4. The method according to claim 1, wherein the first slurry composition of the (d) step comprises hydrochloric acid as a pH adjusting agent.

5. The method according to claim 1, wherein the first additive of the first slurry composition are selected from the group consisting of alpha-cellulose, carboxymethylcellulose sodium salt, methyl vinyl ether, poly(acrylic acid), poly(ethylene glycol), poly-galacturonic acid and combinations thereof.

6. The method according to claim 1, wherein a polishing selectivity ratio of the first slurry composition for nitride film:oxide film is 1:20˜1:200.

7. The method according to claim 1, wherein the first slurry composition comprises pure water as the solvent, a CeO₂ as the abrasive and the first additive, wherein the abrasive is present in an amount ranging from 0.5 to 2 weight parts and the first additive is present in an amount ranging from 0.1 to 1.5 weight parts based on the 100 weight parts of the solvent respectively.

8. The method according to claim 1, wherein the first slurry composition comprising a pure water as the solvent, a SiO₂ as the abrasive and the first additive, wherein the abrasive is present in an amount ranging from 10 to 33 weight parts and the first additive is present in an amount ranging from 0.1 to 1.5 weight parts based on the 100 weight parts of the solvent respectively.

9. The method according to claim 1, wherein the second slurry composition of the (h) step comprises phosphoric acid as a pH adjusting agent.

10. The method according to claim 1, wherein the second slurry composition of the (h) step has a pH ranging from 10 to 11.

11. The method according to claim 1, wherein the second additives are selected from the group consisting of tetraethyl ammonium hydroxide, tetrabutyl ammonium hydroxide, dimethylamine, methylamine, tetramethyl ammonium hydroxide, and combinations thereof.

12. The method according to claim 1, wherein a polishing selectivity ratio of the second slurry composition for polysilicon:oxide film is 1:50˜1:300.

13. The method according to claim 1, wherein the second slurry composition comprises the second additive in an amount ranging from 0.5 to 5 weight parts based on the 100 weight parts of the solvent.

14. The method according to claim 1, wherein the second slurry composition comprises the abrasive in an amount ranging from 0.6 to 12 weight parts based on the 100 weight parts of the solvent.

15. The method according to claim 1, wherein the (d) step comprises:
a first step of performing a CMP process using an oxide film slurry with a pH ranging from 7 to 8 including an abrasive of SiO₂, which is finished up when the isolation film on the pad nitride film comes to be a predetermined thickness; and
a second step of performing a CMP process using the first slurry to expose the pad nitride film.

16. The method according to claim 15, wherein the thickness of the remaining isolation oxide film after CMP in the first step is 1˜50% of that before CMP in the first step.

17. The method according to claim 15, wherein a polishing selectivity ratio of the slurry composition for nitride film:oxide film is 1:2˜4.
